(19) United States
(12) Patent Application Publication
(10) Pub. No.: US 2025/0203990 A1
(43) Pub. Date: Jun. 19, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Meng-Huan JAO, Hsinchu (TW); Chen Luo CHENG, Hsinchu (TW); Sheng-Tsung WANG, Hsinchu (TW); Chia-Hao CHANG, Hsinchu (TW); Huan-Chieh SU, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/538,036

(22) Filed: Dec. 13, 2023

(51) Int. Cl. H01L 29/66; H01L 29/06; H01L 29/15; H01L 29/78

(52) U.S. Cl. CPC H10D 64/018; H10D 30/611; H10D 62/117; H10D 62/815; H10D 64/021

(57) ABSTRACT

A semiconductor device includes a substrate, a first active structure, a conductive portion and a first helmet. The first active structure is formed on the substrate and includes a plurality of first active channel sheets and a plurality of first metal gate structures vertically stacked to each other, wherein the topmost first metal gate structure includes a first inner spacer. The conductive portion is connected with the topmost first active channel sheet. The first helmet is formed above the first inner spacer and covers a lateral surface of the conductive portion.

### BACKGROUND

A semiconductor device normally includes at least one first active structure including a plurality of active channel sheets. However, in an etching process for the dummy gate above the first active structure, the topmost active channel sheet is easy to be damaged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor device according to an embodiment of the present disclosure; and

FIGS. 2A to 2L illustrate schematic diagrams of manufacturing processes of the semiconductor device in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

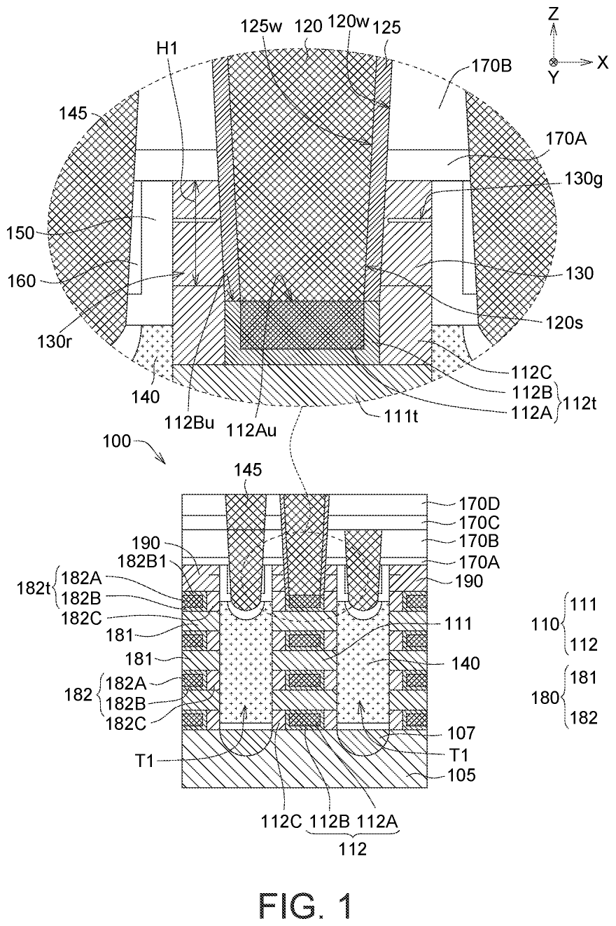

Referring to FIG. 1, FIG. 1 illustrates a schematic diagram of a cross-sectional view of a semiconductor device 100 according to an embodiment of the present disclosure. The semiconductor device 100 may include a substrate 105, at least one silicon layer 107, at least one first active structure 110, a plurality of first inner spacers 112C, at least one conductive portion (or conductive via) 120, at least one liner 125, at least one first helmet 130, at least one epitaxy layer 140, at least one conductive portion 145, at least one contact etch stop layer (CESL) 150, at least one oxide layer 160, a plurality of dielectric layers (for example, a first dielectric layer 170A, a second dielectric layer 170B, a third dielectric layer 170C and a fourth dielectric layer 170D), at least one second active structure 180, a plurality of second inner spacers 182C and at least one second helmet 190. The first active structure 110 is formed on the substrate 105 and includes a plurality of first active channel sheets 111 and a plurality of first metal gate structures 112 vertically stacked to each other. The first helmet 130 is formed above the topmost first inner spacer 112C and covers a lateral surface 120s of the conductive portion 120 (or a lateral surface of the liner 125). As a result, the first helmet 130 and/or the topmost first metal gate structure 112t may protect the topmost first active channel sheet 111t, and accordingly the topmost first active channel sheet 111t may prevent from being damaged in etching process for the dummy gate structure.

As illustrated in FIG. 1 the substrate 105 is, for example, silicon wafer. The silicon layer 107 is formed within a trench T1 between adjacent two of the first active structures 110, and located between the substrate 105 and the epitaxy layer 140. Each epitaxy layer 140 may be a source or a drain of a transistor.

As illustrated in FIG. 1, the first active channel sheet 111 may be formed of a material, for example, silicon. One of the first metal gate structures 112 is formed between adjacent two of the first active channel sheets 111. Each first metal gate structure 112 includes a first metal portion 112A and a first high-k dielectric portion 112B, wherein the first metal portion 112A may be surrounded by the first high-k dielectric portion 112B, the first high-k dielectric portion 112B covers a portion of the first active channel sheet 111, the first inner spacer 112C is formed on a lateral surface of the first high-k dielectric portion 112B or the first active channel sheet 111.

As illustrated in FIG. 1, the conductive portion 120 and the linear 125 extend to the topmost first metal gate structure 112t. Furthermore, the conductive portion 120 and the linear 125 extend to the topmost first metal gate structure 112t through the fourth dielectric layer 170D, the third dielectric layer 170C, the second dielectric layer 170, the first dielectric layer 170A and the first helmet 130. In addition, the first inner spacer 112C of the topmost first metal gate structure 112t protrudes beyond an upper surface 112Bu of the first high-k dielectric portion 112B and an upper surface 112Au of the first metal portion 112A. In an embodiment, the conductive portion 120 is, for example, gate via (also called “VG”).

As illustrated in FIG. 1, the liner 125 is formed on or covers a sidewall 120w including a first sidewall of the first dielectric layer 170A, a first sidewall of the second dielectric layer 170B, a first sidewall of the third dielectric layer 170C, a first sidewall of the fourth dielectric layer 170D, a first sidewall of the first helmet 130 and a first sidewall of the topmost first inner spacer 112C. Furthermore, the sidewall 120w has a first flatness, and a second sidewall 125w of the liner 125 has a second flatness, wherein the second flatness is less than the first flatness. As a result, the conductive portion 120 is formed on or in contact with pure material (for example, the material of the linear 125) and the flatter sidewall of the liner 125, and accordingly it may increase the bonding between the liner 125 and the conductive portion 120. In addition, the liner 125 may be formed of a material including, for example, silicon carbide (SiC), silicon nitride (SiN), silicon nitrogen carbon oxide (SiOCN), silicon oxycarbide (SiOC), silicon carbonitride (SiCN), silicon oxide (SiO), etc. In addition, the liner 125 has a thickness ranging between, for example, 0.1 nanometer (nm) to 10 nm.

In addition, the first helmet 130 may be formed of a material the same as that of the first inner spacer 112C. In an embodiment, the first helmet 130 and the first inner spacer 112C may be formed of, for example, a dielectric material including, for example, SiC, SiN, SiOCN, SiOC, SiCN, SiO, etc.

As illustrated in FIG. 1, depending on a height H1 of a space 130r within which the first helmet 130 is formed, the first helmet 130 may form at least one gap 130g in deposition process for the first helmet material. Furthermore, in deposition process for the first helmet material, due to the height H1 being greater, the first helmet material may not fill the space 130r and form the gap 130g. However, if the height H1 of the space 130r is less enough, the gap 130g may be not formed. In addition, the height H1 (or the thickness of the first helmet 130) ranges between, for example, 1 nm to 20 nm.

As illustrated in FIG. 1, there is a trench T1 between adjacent two of the first active structures 110. The silicon layer 107 is formed within a bottom portion of the trench T1, and the epitaxy layer 140 is formed on or above the silicon layer 107 and located between the silicon layer 107 and the CESL 150. The conductive portion 145 passes through the oxide layer 160 and at least one of the first dielectric layer 170A, the second dielectric layer 170B, the third dielectric layer 170C and the fourth dielectric layer 170D to be electrically connected with the epitaxy layer 140. In an embodiment, the conductive portion 145 is called “MD (metal over diffusion)”. In addition, the conductive portion 145 may be formed of a material including, for example, tungsten (W), ruthenium (Ru), cobalt (Co), copper (Cu), molybdenum (Mo), titanium (Ti), tantalum nitride (TaN), titanium nitride (TiN), or a combination thereof.

As illustrated in FIG. 1, the CESL 150 is formed above the epitaxy layer 140. The CESL 150 is formed between the epitaxy layer 140 and the oxide layer 160. The oxide layer 160 is formed on the CESL 150. In an embodiment, the CESL 150 may be formed of a material including SiO, SiN, SiOC, SiON or SiOCN.

As illustrated in FIG. 1, the second active structure 180 includes a plurality of second active channel sheets 181 and a plurality of second metal gate structures 182 vertically stacked to each other. Each second metal gate structure 182 includes a second metal portion 182A and a second high-k dielectric portion 182B, wherein the second high-k layer 182B covers the second metal portion 182A, and the second inner spacer 182C covers a lateral surface of the second high-k dielectric portion 182B or the second metal portion 182A. In the present embodiment, the second high-k dielectric portion 182B includes an upper portion 182B1 covering the upper surface of the second metal layer 182A. In addition, the second helmet 190 covers the topmost second metal gate structure 182t and the topmost second inner spacer 182C. Furthermore, the second helmet 190 covers or is contact with an upper surface of the second high-k dielectric portion 182B and an upper surface of the second inner spacer 182C. In the present embodiment, there is no hole passing the second helmet 190, and thus the topmost second metal gate structure 182t is not exposed from the second helmet 190. In addition, the second helmet 190 may have the gap the same as or similar to the gap 130g of the first helmet 130. The second helmet 190 may include the features (for example, the size, material and/or structure) the same as or similar to that of the first helmet 130.

In addition, the second metal portion 182A may be formed of a material the same as or similar to that of the first metal portion 112A, the second high-k dielectric portion 182B may be formed of a material the same as or similar to that of the first high-k dielectric portion 112B, and the second inner spacer 182C may be formed of a material the same as or similar to that of the first inner spacer 112C. In addition, the second metal portion 182A and the first metal portion 112A may be formed in the same process, the second high-k dielectric portion 182B and the first high-k dielectric portion 112B may be formed in the same process, and the second inner spacer 182C and the first inner spacer 112C may be formed in the same process.

The high-k dielectric layer may be formed of a material including: (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

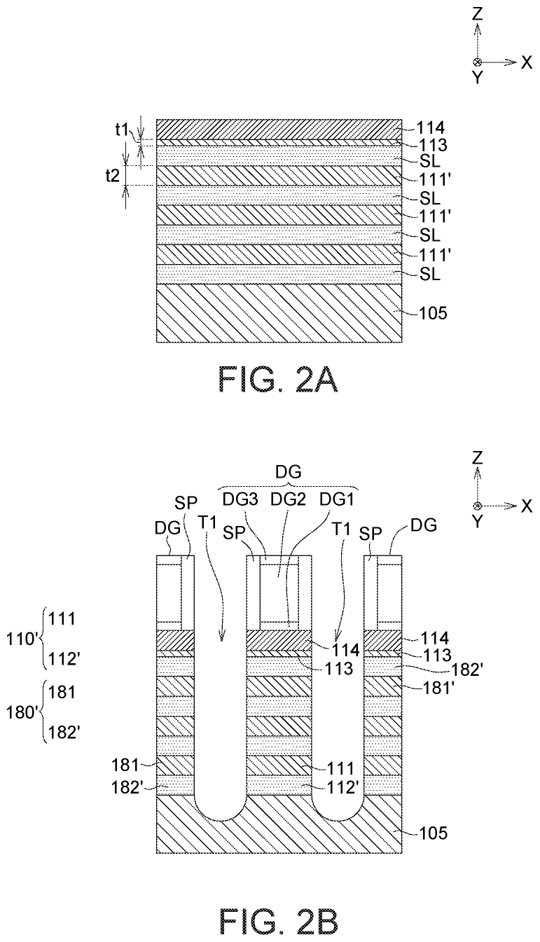

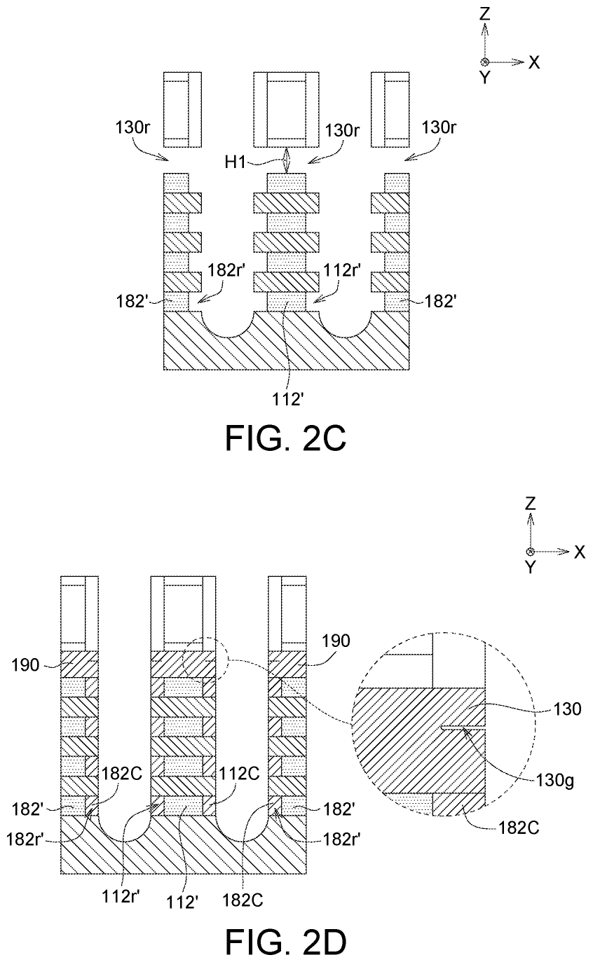

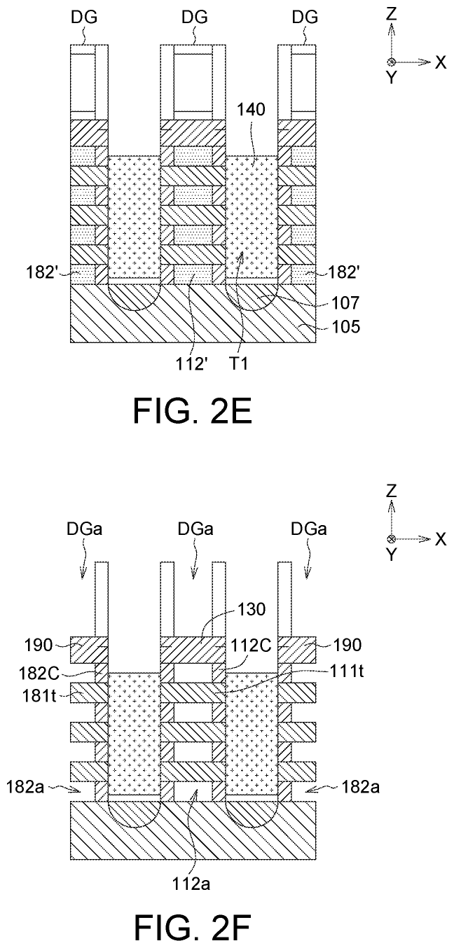

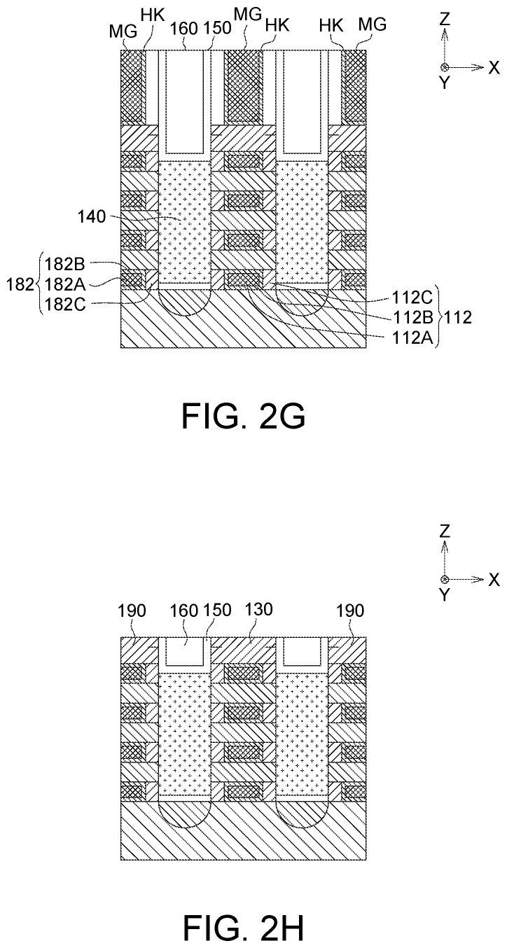

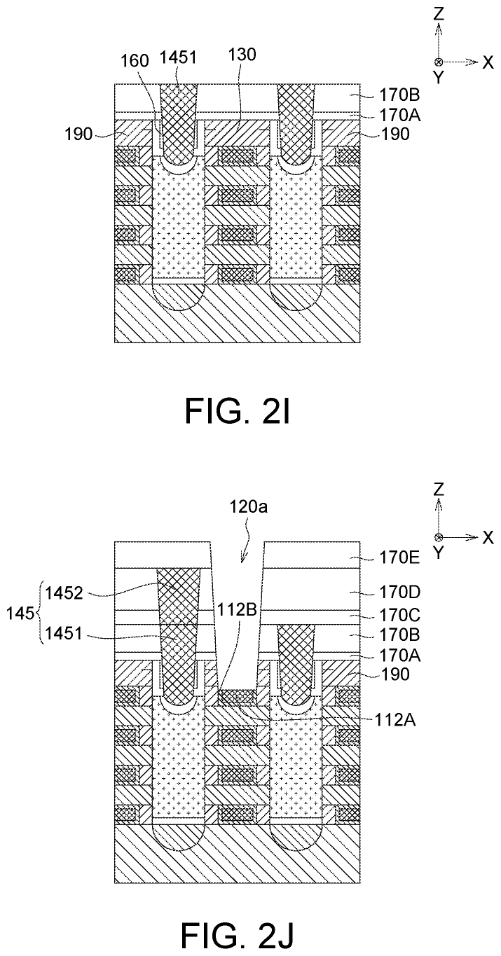

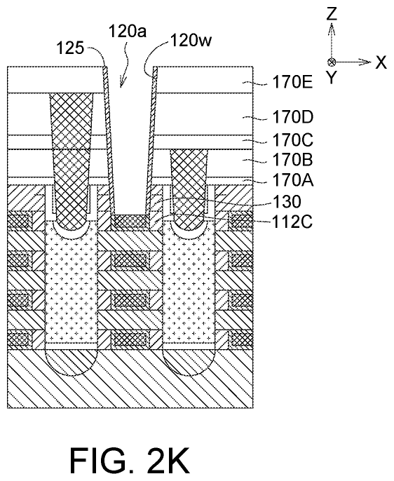

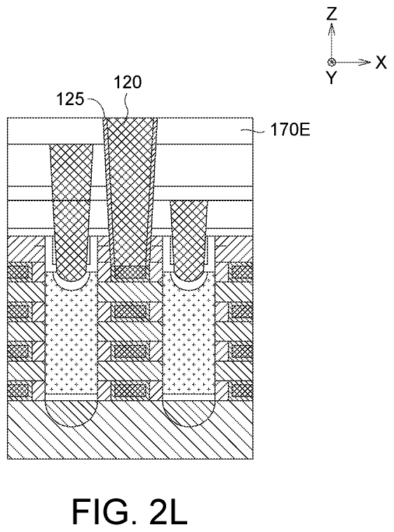

Referring to FIGS. 2A to 2 L, FIGS. 2A to 2L illustrate schematic diagrams of manufacturing processes of the semiconductor device 100 in FIG. 1.

As illustrated in FIG. 2A, a superlattice structure including, for example, a plurality of sheet layers 111′, a plurality of silicon germanium (SiGe) layers SL, a first separation layer 113 and a second separation layers 114 is formed on the substrate 105 by using deposition, wherein one of the SiGe layers SL is formed between the adjacent two of the sheet layers 112′, and the first separation layer 113 is formed between the topmost SiGe layer SL and the second separation layer 114. The sheet layer 111′ and the first separation layer 113 may be formed of a material including, for example, silicon. The sheet layer 111′ has a first thickness t1, and the first separation layer 113 has a second thickness t2, wherein the second thickness t2 is less than the first thickness t1. In an embodiment, the first thickness t1 may range between, for example, 5 nm and 15 nm, and the second thickness t2 may range between, for example, 1 nm and 4 nm. Due to the first separation layer 113 is thin enough, the first separation layer 113 may be removed with the removal of the second separation layer 114. In addition, the second separation layer 114 may be formed of a material the same as or similar to that of SiGe layer SL, for example, silicon germanium. In an embodiment, the second separation layer 114 has a first concentration, and the SiGe layer SL has a second concentration, wherein the second concentration is greater than the first concentration for etching selectivity.

As illustrated in FIG. 2A, a portion of each sheet layer 111′, a portion of each SiGe layer SL, a portion of the first separation layer 113 and a portion of the second separation layer 114 are removed to form at least one interval (not illustrated) through a patterned pad oxide layer (not illustrated) and hard mask (not illustrated) by using, for example, etching, etc. A remaining portion of portion of each sheet layer 111′, a remaining portion of each SiGe layer SL, a remaining portion of the first separation layer 113 and a remaining portion of the second separation layer 114 form at least one fin structure in the first direction (for example, X axis). The region of one fin structure defines one OD (oxide diffusion) region, for example. Then, the patterned pad oxide layer and hard mask is removed by, for example, etching or CMP (Chemical-Mechanical Planarization).

As illustrated in FIG. 2B, at least one dummy gate structure DG is formed on the fin structure in FIG. 2A. The dummy gate structure DG includes an oxide layer DG1, a dummy gate layer DG2 and a mask layer DG3, wherein the oxide layer DG1 is formed on the fin structures, the dummy gate layer DG2 is formed over the oxide layer DG1, and the mask layer DG3 is formed over the dummy gate layer DG2. In an embodiment, the dummy gate layer DG2 may be deposited over the oxide layer DG1 and then planarized, such as by CMP, and then the mask layer DG3 may be deposited over the dummy gate layer DG2.

In addition, the dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be formed of other materials that have a high etching selectivity from the etching of isolation regions. The mask layer may include, for example, silicon nitride, silicon oxynitride, or the like.

As illustrated in FIG. 2B, a spacer layer SP over a lateral surface of the dummy gate structure DG is formed by, for example, deposition, etc.

Then, as illustrated in FIG. 2B, at least one trench T1 passing through the fin structure and a portion of the substrate 105 is formed to form at least one first active structure 110′ and at least one second active structure 180′ through the dummy gate structures DG. Each first active structure 110′ includes a plurality of the first active channel sheets 111, a plurality of the first SiGe layers 112′, a portion of the first separation layer 113 and a portion of the second separation layer 114, wherein the first active channel sheets 111 and the first SiGe layers 112′ are stacked to each other. Similarly, each second active structure 180′ includes a plurality of the second active channel sheets 181, a plurality of second SiGe layers 182′, a portion of the first separation layer 113 and a portion of the second separation layer 114, wherein the second active channel sheets 181 and the second SiGe layers 182′ are stacked to each other.

Then, as illustrated in FIG. 2C, the second separation layer 114, the first separation layer 113, a portion of the first SiGe layer 112′ and a portion of the second SiGe layer 182′ in FIG. 2B are removed by using, for example, etching. After removal of the portion of the first SiGe layer 112′ and the portion of the second SiGe layer 182′, a remaining portion of the first SiGe layer 112′ forms a first recess 112r′ and a remaining portion of the second SiGe layer 182′ forms a second recess 182r′. After removal of the second separation layer 114 and the first separation layer 113, at least one space 130r is formed, and the space 130r has the height H1. Due to the first separation layer 113 being thin enough, at least one portion of the first separation layer 113 may be removed with the removal of the second separation layer 114. In addition, due to the second separation layer 114 and the SiGe layer SL being different in concentration, the etching rate of the second separation layer 114 is greater than the etching rate of the SiGe layer SL, and thus the second separation layer 114 may be fully removed while merely a portion of the SiGe layer SL is removed.

Then, as illustrated in FIG. 2D, the first inner spacer 112C formed within the first recess 112r′, the second inner spacer 182C formed within the second recess 182r′, the first helmet 130 within the space 130r and the second helmet 190 within the space 130r are formed by using, for example, deposition. Depending on the height H1 of the space 130r within which the first helmet 130 is formed, the first helmet 130 may form at least one gap 130g. Furthermore, in deposition process for the first helmet material, due to the height H1 being greater, the first helmet material may not fill the space 130r and form the gap 130g. However, if the height H1 of the space 130r is less enough, the gap 130g may be not formed. In addition, the second helmet 190 may have the gap the same as or similar to the gap 130g of the first helmet 130. The second helmet 190 includes the features (for example, the size, material and/or structure) the same as or similar to that of the first helmet 130.

Then, as illustrated in FIG. 2E, at least one silicon layer 107 is formed the bottom portion of the trench T1, and then at least one epitaxy layer 140 is formed on silicon layer 107 by using, for example, epitaxy process.

Then, as illustrated in FIG. 2F, the second SiGe layers 182′ and the first SiGe layers 112′ in FIG. 2E are removed to form a plurality of spaces 182a and a plurality of spaces 112a by using, for example, etching. In addition, the dummy gate structures DG in FIG. 2E are removed to form a plurality of spaces DGa by using, for example, etching. Due to the protection of the first helmet 130 and the first inner spacer 112C, the topmost first active channel sheet 111t may be prevented from being damaged during process of etching. Similarly, due to the protection of the second helmet 190 and the second inner spacer 182C, the topmost second active channel sheet 181t may be prevented from being damaged during process of etching.

Then, as illustrated in FIG. 2G, the first high-k dielectric portion 112B within the space 112a in FIG. 2F, the second high-k dielectric portion 182B within the space 182a in FIG. 2F and the high-k dielectric portion HK within the space DGa in FIG. 2F are formed by using, for example, deposition, etc. Then, the first metal portion 112A on the first high-k dielectric portion 112B, the second metal portion 182A on the second high-k dielectric portion 182B and the metal portion MG on the high-k dielectric portion HK are formed by using, for example, deposition, etc. The CESL 150 within the trench T1 and above the epitaxy layer 140 is formed by using, for example, deposition, etc., and the oxide layer 160 on the CESL 150 is formed by using, for example, deposition, etc. In an embodiment, the CESL 150 may be formed prior to formation of the metal portion MG.

Then, as illustrated in FIG. 2H, the metal portion MG, the high-k dielectric portion HK, a portion of the CESL 150 and a portion of the oxide layer 160 in FIG. 2G may be planarized by using, for example, CMP. After CMP, the first helmet 130 and the second helmet 190 are exposed. In another embodiment, the gap 130g may be removed by the CMP.

Then, as illustrated in FIG. 2I, the first dielectric layer 170A over the first helmet 130, the CESL 150, the oxide layer 160 and the second helmet 190, is formed by using, for example, deposition. Then, the second dielectric layer 170B over the first dielectric layer 170A is formed by using, for example, deposition. Then, a portion 1451 of the conductive portion 145 passing through the second dielectric layer 170B, the first dielectric layer 170A and the oxide layer 160 is formed by using, for example, lithography, deposition, etc.

Then, as illustrated in FIG. 2J, the third dielectric layer 170C over the second cover layer 170B and the fourth dielectric layer 170D over the third dielectric layer 170C are formed by using, for example, deposition, etc. Then, another portion 1452 of the conductive portion 145 passing through the third dielectric layer 170C and the fourth dielectric layer 170D is formed by using, for example, lithography, deposition, etc. Then, a fifth dielectric layer 170E over the fourth dielectric layer 170D and the conductive portion 145 is formed by using, for example, deposition, etc. Then, a hole 120a passing through the fifth dielectric layer 170E, the fourth dielectric layer 170D, the third dielectric layer 170C, the second dielectric layer 170B, the first dielectric layer 170A, the first helmet 130 and a portion of the first high-k dielectric portion 112B is formed to expose the topmost first metal gate structure 112t by using, for example, lithography, deposition, etc.

Then, as illustrated in FIG. 2K, the linear 125 covering the sidewall 120w including the first sidewall of the first dielectric layer 170A, the first sidewall of the second dielectric layer 170B, the first sidewall of the third dielectric layer 170C, the first sidewall of the fourth dielectric layer 170D, the first sidewall of the first helmet 130 and the first sidewall of the topmost first inner spacer 112C is formed by using, for example, deposition, etc. The sidewall 120w has a first flatness, and a second sidewall 125w of the liner 125 has a second flatness, wherein the second flatness is less than the first flatness. As a result, the subsequent conductive portion 120 is formed on or in contact with pure material and the flatter sidewall of the liner 125, and accordingly it may increase the bonding between the liner 125 and the conductive portion 120.

Then, as illustrated in FIG. 2L, the conductive portion 120 over the linear 125 and filling the hole 120a and covering the sidewall 120w is formed by using, for example, deposition, etc.

Then, the fifth dielectric layer 170E, a portion of the conductive portion 120 and a portion of the linear 125 are removed to form the semiconductor device 100 by using, for example, CMP.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a first active structure formed on a substrate. The first active structure includes a plurality of first active channel sheets and a plurality of first metal gate structures vertically stacked to each other, wherein the topmost first metal gate structure covers the topmost active channel sheet. As a result, the topmost first metal gate structure may protect the topmost first active channel sheet, and accordingly the topmost first active channel sheet may prevent from being damaged in etching process for the dummy gate structure.

Example embodiment 1: a semiconductor device includes a substrate, a first active structure, a plurality of first inner spacers, a conductive portion and a first helmet. The first active structure is formed on the substrate and includes a plurality of first active channel sheets and a plurality of first metal gate structures vertically stacked to each other. Each first inner spacer is formed on a lateral surface of the corresponding first metal gate structure. The conductive portion is connected with the topmost first active channel sheet. The first helmet is formed above the topmost first inner spacer and covers a lateral surface of the conductive portion.

Example embodiment 2 based on Example embodiment 1: the semiconductor device further includes a plurality of dielectric layers formed on the first active structure. The conductive portion passes through the dielectric layers and the first helmet, and the semiconductor device further includes a liner covers a first sidewall of each of the dielectric layers.

Example embodiment 3 based on Example embodiment 1: wherein the first sidewalls have a first flatness, a second sidewall of the liner has a second flatness, and the second flatness is less than the first flatness.

Example embodiment 4 based on Example embodiment 2: the topmost first metal gate structure further includes a first metal portion and a first high-k layer. The first high-k layer covers the first metal portion. The linear extends to the first metal portion through the first high-k layer.

Example embodiment 5 based on Example embodiment 1: the topmost first metal gate structure further includes a first metal portion and a first high-k layer covering the first metal portion. The conductive portion extends to the first metal portion through the first high-k layer.

Example embodiment 6 based on Example embodiment 5: the first inner spacer protrudes beyond an upper surface of the first metal portion and an upper surface of the first high-k layer.

Example embodiment 7 based on Example embodiment 1: the semiconductor device further includes a second active structure, a plurality of second inner spacers and a second helmet. The second active structure is formed on the substrate and includes a plurality of second active channel sheets and a plurality of second metal gate structures vertically stacked to each other. Each second inner spacer is formed on a lateral surface of the corresponding second metal gate structure. The second helmet covers the topmost second metal gate structure and the topmost second inner spacer.

Example embodiment 8 based on Example embodiment 7: the topmost second metal gate structure further includes a second metal portion and a second high-k layer. The second high-k layer includes an upper portion, wherein the upper portion covers an upper surface of the second metal portion.

Example embodiment 9 based on Example embodiment 1: the first inner spacer is formed of a material the same as that of the first helmet.

Example embodiment 10 based on Example embodiment 9: the first helmet has a thickness ranging between 1 nm and 20 nm.

Example embodiment 11: a semiconductor device includes a substrate, an active structure, a plurality of inner spacer and a helmet. The active structure is formed on the substrate and includes a plurality of active channel sheets and a plurality of metal gate structures vertically stacked to each other. Each inner spacer is formed on a lateral surface of the corresponding first metal gate structure. The helmet covers the inner spacer of the topmost metal gate structure.

Example embodiment 12 based on Example embodiment 11: the topmost metal gate structure further includes a high-k dielectric portion and a metal portion surrounding the high-k dielectric portion, and the helmet further covers the high-k dielectric portion.

Example embodiment 13 based on Example embodiment 12: the helmet is in contact with the high-k dielectric portion.

Example embodiment 14 based on Example embodiment 12; the high-k layer includes an upper portion, wherein the upper portion covers an upper surface of the metal portion.

Example embodiment 15 based on Example embodiment 11: the inner spacer is formed of a material the same as that of the helmet.

Example embodiment 16 based on Example embodiment 11: the helmet has a thickness ranging between 1 nm and 20 nm.

Example embodiment 17: a manufacturing method for a semiconductor device includes the following steps: forming a first active structure on a substrate, wherein the first active structure includes a plurality of first active channel sheets and a plurality of first metal gate structures vertically stacked to each other; forming a plurality of inner spacers, wherein each inner spacer is formed on a lateral surface of the corresponding first metal gate structure; forming a first helmet above the first inner spacer; and forming a conductive portion to be connected with the topmost first active channel sheet, wherein the first helmet covers a lateral surface of the conductive portion.

Example embodiment 18 based on Example embodiment 17: before forming the conductive portion, the semiconductor method further includes: forming a plurality of dielectric layers cover the first active structure; forming a hole to pass through the dielectric layers; and forming a liner to cover a sidewall of the hole.

Example embodiment 19 based on Example embodiment 17: the first helmet and the first inner spacer are formed in the same process.

Example embodiment 20 based on Example embodiment 17: the semiconductor method further includes: forming a superlattice structure on the substrate, wherein the superlattice structure includes a plurality of sheet layers, a plurality of SiGe layers, a first separation layer and a second separation layers, and one of the SiGe layers is formed between the adjacent two of the sheet layers, and the first separation layer is formed between the topmost SiGe layer and the second separation layer; removing the first separation layer and the second separation layer to form a space; and forming the first cover within the space.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first active structure formed on the substrate and comprising a plurality of first active channel sheets and a plurality of first metal gate structures vertically stacked to each other;
a plurality of first inner spacers each formed on a lateral surface of the corresponding first metal gate structure;
a conductive portion connected with the topmost first active channel sheet; and
a first helmet formed above the topmost first inner spacer and covering a lateral surface of the conductive portion.

2. The semiconductor device as claimed in claim 1, further comprising:
a plurality of dielectric layers formed on the first active structure;
wherein the conductive portion passes through the dielectric layers and the first helmet, and the semiconductor device further comprises:
a liner covering a first sidewall of each of the dielectric layers.

3. The semiconductor device as claimed in claim 2, wherein the first sidewalls have a first flatness, a second sidewall of the liner has a second flatness, and the second flatness is less than the first flatness.

4. The semiconductor device as claimed in claim 2, wherein the topmost first metal gate structure further comprises:
a first metal portion; and
a first high-k layer covering the first metal portion;
wherein the linear extends to the first metal portion through the first high-k layer.

5. The semiconductor device as claimed in claim 1, wherein the topmost first metal gate structure further comprises:
a first metal portion; and
a first high-k layer covering the first metal portion;
wherein the conductive portion extends to the first metal portion through the first high-k layer.

6. The semiconductor device as claimed in claim 5, wherein the first inner spacer protrudes beyond an upper surface of the first metal portion and an upper surface of the first high-k layer.

7. The semiconductor device as claimed in claim 1, further comprising:
a second active structure formed on the substrate and comprising a plurality of second active channel sheets and a plurality of second metal gate structures vertically stacked to each other; and
a plurality of second inner spacers each formed on a lateral surface of the corresponding second metal gate structure; and
a second helmet covering the topmost second metal gate structure and the topmost second inner spacer.

8. The semiconductor device as claimed in claim 7, wherein the topmost second metal gate structure further comprises:
a second metal portion; and
a second high-k layer comprising an upper portion, wherein the upper portion covers an upper surface of the second metal portion.

9. The semiconductor device as claimed in claim 1, wherein the first inner spacer is formed of a material the same as that of the first helmet.

10. The semiconductor device as claimed in claim 1, wherein the first helmet has a thickness ranging between 1 nanometer (nm) and 20 nm.

11. A semiconductor device, comprising:
a substrate;
an active structure formed on the substrate and comprising a plurality of active channel sheets and a plurality of metal gate structures vertically stacked to each other;
a plurality of inner spacers each formed on a lateral surface of the corresponding first metal gate structure; and
a helmet covering the topmost inner spacer and the topmost metal gate structure.

12. The semiconductor device as claimed in claim 11, wherein the topmost metal gate structure further comprises a high-k dielectric portion and a metal portion surrounding the high-k dielectric portion, and the helmet further covers the high-k dielectric portion.

13. The semiconductor device as claimed in claim 12, wherein the helmet is in contact with the high-k dielectric portion.

14. The semiconductor device as claimed in claim 12, wherein the high-k layer comprises an upper portion, wherein the upper portion covers an upper surface of the metal portion.

15. The semiconductor device as claimed in claim 11, wherein the inner spacer is formed of a material the same as that of the helmet.

16. The semiconductor device as claimed in claim 11, wherein the helmet has a thickness ranging between 1 nm and 20 nm.

17. A manufacturing method for a semiconductor device, comprising:
forming a first active structure on a substrate, wherein the first active structure comprises a plurality of first active channel sheets and a plurality of first metal gate structures vertically stacked to each other;
forming a plurality of inner spacers, wherein each inner spacer is formed on a lateral surface of the corresponding first metal gate structure;
forming a first helmet above the first inner spacer; and
forming a conductive portion to be connected with the topmost first active channel sheet, wherein the first helmet covers a lateral surface of the conductive portion.

18. The semiconductor method as claimed in claim 17, before forming the conductive portion, the semiconductor method further comprising:
forming a plurality of dielectric layers cover the first active structure;
forming a hole to pass through the dielectric layers; and
forming a liner to cover a sidewall of the hole.

19. The semiconductor method as claimed in claim 17, wherein the first helmet and the first inner spacer are formed in the same process.

20. The semiconductor method as claimed in claim 17, further comprising:
forming a superlattice structure on the substrate, wherein the superlattice structure comprising a plurality of sheet layers, a plurality of silicon germanium (SiGe) layers, a first separation layer and a second separation layers, and one of the SiGe layers is formed between the adjacent two of the sheet layers, and the first separation layer is formed between the topmost SiGe layer and the second separation layer;
removing the first separation layer and the second separation layer to form a space; and
forming the first cover within the space.
